(19) United States
(12) Patent Application Publication
(10) Pub. No.: US 2008/0012096 A1
(43) Pub. Date: Jan. 17, 2008

(54) SEMICONDUCTOR CHIP AND METHOD OF FORMING THE SAME

(75) Inventors: Wha-Su SIN, Chungcheongnam-do (KR); Heui-Seog KIM, Chungcheongnam-do (KR); Sang-Jun KIM, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/776,489

(22) Filed: Jul. 11, 2007

(30) Foreign Application Priority Data
Jul. 12, 2006 (KR) 2006-65552

(51) Int. Cl. H01L 23/544; H01L 21/30

(52) U.S. Cl. 257/620; 438/462; 257/E21.211; 257/E23.179

(57) ABSTRACT

A semiconductor chip and method of forming the same are described. The semiconductor chip includes a first surface, a second surface opposite to the first surface, and a rim side connecting the first surface and the second surface. At least one groove is defined within rim side. The groove is curved and extends from the first surface to the second surface.

### CROSS-REFERENCE TO RELATED PATENT APPLICATION

This patent application claims priority under 35 U.S.C. § 119 of Korean Patent Application 2006-65552 filed on Jul. 12, 2006, the entirety of which is hereby incorporated by reference.

### BACKGROUND

1. Field of Invention

Embodiments of the present invention relate generally to semiconductor chips and methods of forming the same.

2. Description of the Related Art

The use of semiconductor chips is significantly increasing in highly advanced industrial fields. Within a semiconductor chip, various semiconductor devices may be formed to perform various functions. Accordingly, semiconductor processes are performed upon a semiconductor wafer to form a plurality of chip areas each where a plurality of semiconductor devices are formed. The chip areas are spaced apart from each other by a scribe region. The semiconductor wafer is sawed along the scribe region to separate the chip areas. Each separate chip area acts as a semiconductor chip. Such semiconductor chips are packaged to be used and/or applied to various industrial fields.

With the trends toward higher integration density of semiconductor devices, sizes of semiconductor packages are decreasing. In recent years, chip size packages having the same sizes as semiconductor chips have been introduced. As sizes of such semiconductor packages continue to decrease in size, semiconductor chips must be made thinner. For example, semiconductor chips having a thickness of tens of micrometers have recently been required.

Several problems result from the decrease in thickness of semiconductor chips. For example, warpage of a wafer occurs when the wafer ground to be thin, as illustrated in FIG. 1.

FIG. 1 is a side view illustrating the wafer warpage. When the back surface of a wafer W is ground to a thickness of tens of micrometers, the wafer W may be warped. The wafer warpage results from stress induced by material layers (e.g., an oxide layer, a metal layer, etc.) formed on the wafer W. Due to the wafer warpage, semiconductor chips become cracked and damaged. In addition, the wafer warpage makes it extremely hard to saw a wafer.

### SUMMARY

Exemplary embodiments of the present invention provide a semiconductor chip and a method of forming the same.

One embodiment can be generally characterized as a semiconductor chip that includes a first surface, a second surface opposite to the first surface, a rim side connecting the first surface and the second surface, and at least one groove defined within rim side. The groove may be extend from the first surface to the second surface and at least a portion of the groove is curved.

Another embodiment can be generally characterized as a method of forming a semiconductor chip that includes preparing a wafer comprising a first surface and a second surface opposite to the first surface, wherein a plurality of chip areas are arranged on the first surface and a scribe region is located between the plurality of chip areas, forming a hole within a portion of the scribe region and a chip area, the hole penetrating the wafer wherein at least a portion of the hole is curved, and dicing the wafer along the scribe region to separate adjacent ones of the plurality of chip areas, wherein a separated chip areas is a semiconductor chip and wherein a portion of a rim side connecting the first and second surfaces corresponds to a portion of a sidewall of the hole.

Yet another embodiment can be generally characterized as a semiconductor chip that includes a first surface, a second surface opposite to the first surface, a side surface connecting the first surface and the second surface, and at least one groove defined within side surface and extending from the first surface to the second surface. The groove may divide the side surface into two portions which are substantially coplanar.

Still another embodiment can be generally characterized as a semiconductor chip that includes a first surface, a second surface opposite to the first surface, a rim side connecting the first surface and the second surface, the rim side comprising a first side surface extending in a first direction, a second side surface extending in a second direction and a corner connecting the first and second side surfaces, and at least one groove defined within at least one of the first and second side surfaces, wherein the at least one groove extends from the first surface to the second surface and wherein the groove is spaced apart from the corner.

### BRIEF DESCRIPTION OF THE DRAWINGS

FIG. 1 illustrates a side view illustrating the warpage of a wafer;

FIGS. 2A, 3A and 4A are top plan views illustrating a method of forming a semiconductor chip according to an embodiment of the present invention;

FIGS. 2B, 3B and 4B are cross-sectional views taken along lines I-I of FIGS. 2A, 3A and 4A, respectively;

FIGS. 5 and 6 are a perspective view and a top plan view of a semiconductor chip according to an embodiment of the present invention, respectively;

FIGS. 7 through 9 are cross-sectional views illustrating a modified step of forming holes in the method described with reference to FIGS. 2A through 4A;

FIGS. 10A and 11A are top plan views illustrating a method of forming a semiconductor chip according to another embodiment of the present invention;

FIGS. 10B and 11B are cross-sectional vies taken along lines II-II′ of FIGS. 10A and 11A, respectively; and

FIGS. 12 and 13 are a perspective view and a top plan view of a semiconductor chip according to another embodiment of the present invention, respectively.

### DETAILED DESCRIPTION

Exemplary embodiments of the present invention will now be described more fully hereinafter with reference to the accompanying drawings, in which preferred embodiments of the invention are shown. These embodiments may, however, be realized in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

### Embodiment 1

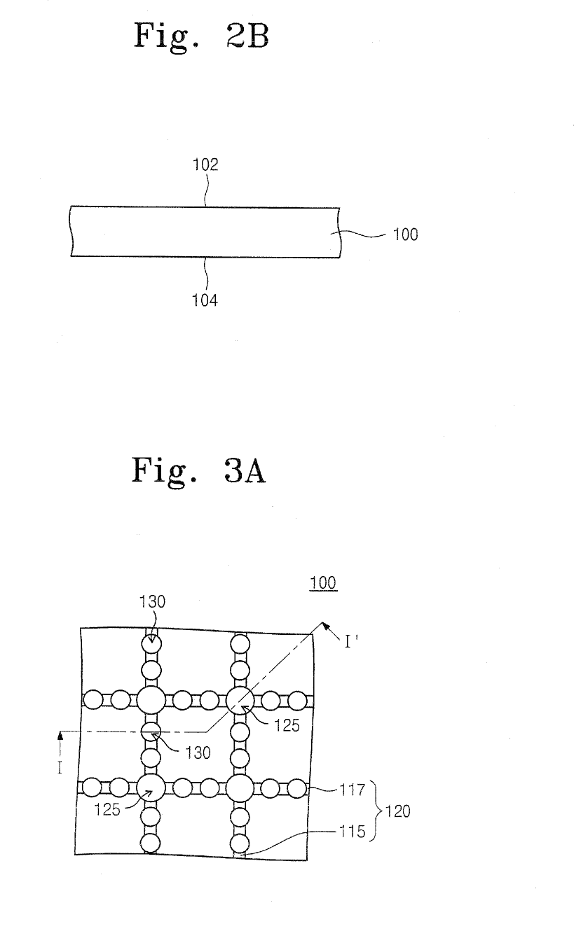

FIGS. 2A, 3A and 4A are top plan views illustrating a method of forming a semiconductor chip according to an embodiment of the present invention. FIGS. 2B, 3B and 4B are cross-sectional views taken along lines I-I′ of FIGS. 2A, 3A and 4A, respectively.

Referring to FIGS. 2A and 2B, a semiconductor wafer (hereinafter referred to as “wafer”) 100 may be provided with a first surface 102 where a plurality of chip areas 110 and a scribe region 120 are formed. The wafer includes a second surface 104 that is opposite to the first surface 102.

The plurality of chip areas 110 are arranged within the plane of the first surface 102. That is, the plurality of chip areas 110 are arranged two-dimensionally on the first surface 102. Semiconductor devices (e.g., semiconductor memory devices or logic devices) may be formed in the respective chip areas 110. The scribe region 120 is disposed between the chip areas 110. Accordingly, the chip areas 110 are spaced apart from each other by the scribe region 120. As illustrated, the scribe region 120 may include a first segment region 115 extending in a first direction and a second segment region 117 extending in a second direction. The first segment region 115 may be substantially linear. The second segment region 117 may also be substantially linear. The First and second directions are different from each other. For example, the first and second directions may be substantially perpendicular to each other. Due to the presence of the scribe region 120, the chip areas 110 may be two-dimensionally arranged along rows and columns to be spaced apart from each other.

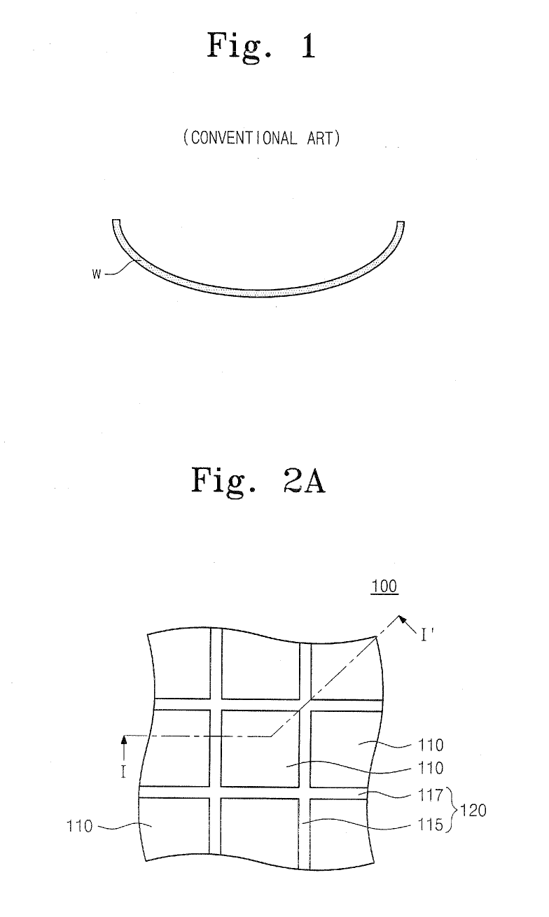

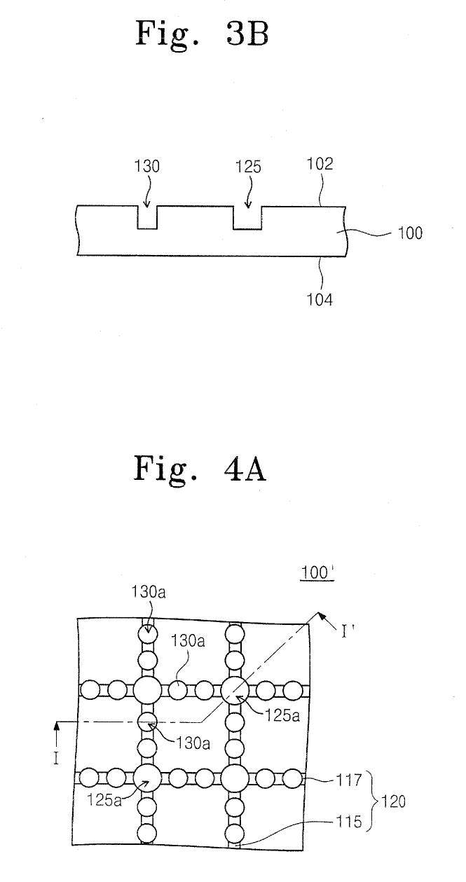

Referring to FIGS. 1A and 3B, a first preliminary hole 125 and a second preliminary hole 130 may be formed within the wafer 100. The first and second preliminary holes 125 and 130 may each be formed to a predetermined depth below the first surface 102 of the wafer 100. In one embodiment, the depth of the first and second preliminary holes 125 and 130 is less than the thickness of the wafer 100 and may be substantially equal to or greater than the thickness of a subsequently formed semiconductor chip.

In one embodiment, the first and second preliminary holes 125 and 130 are formed at a portion of the scribe region 120 and at edge portions of the chip area 110 adjacent to the portion of the scribe region 120. For example, the first preliminary holes 125 may be formed at intersections of the first and second segment regions 115 and 117 and at the corner edges of the chip area 110 adjacent to the intersections. In one embodiment, the first preliminary hole 125 may be substantially cylindrical. In another embodiment, the sidewall of the first preliminary hole 125 may be slanted (e.g., to form a conical first preliminary hole 125). The first preliminary holes 125 may be formed at intersections of the first and second segment regions 115 and 117 and at corner edges of four chip areas 110 adjacent to the intersections. The second preliminary holes 130 may be Formed at side portions, which are portions of at least one of the first and second segment regions 115 and 117, and at the side edges of the chip area 110 adjacent to the side portions. The second preliminary holes 130 may be formed at the side edges of a pair of chip areas 110 adjacent to the side portions. In one embodiment, the second preliminary hole 130 may be substantially cylindrical. In another embodiment, the sidewall of the second preliminary hole 130 may be slanted (e.g., to form a conical second preliminary hole 130).

The first preliminary hole 125 and the second preliminary hole 130 may be spaced apart from each other. The first preliminary holes 125 may be spaced apart from each other and the second preliminary holes 130 may be spaced apart from each other. The first and second preliminary holes 125 and 130 may be two-dimensionally arranged along the scribe region 120 in row and column directions. A diameter of the first preliminary hole 125 may be different from that of the second preliminary hole 130. For example, the diameter of the preliminary hole 125 may be larger than that of the second preliminary hole 130. In another embodiment, the diameters of the first and second preliminary holes 125 and 130 may be substantially equal to each other.

In one embodiment, one or more first and second preliminary holes 125 and 130 may be formed within the wafer 100. In another embodiment, one or more first preliminary holes 125 may be formed within the wafer 100 only. In another embodiment, one or a plurality of second preliminary holes 125 may be formed within the wafer 100 only.

The first and second preliminary holes 125 and 130 may be formed according to a patterning process including, for example, a photolithography process and an etching process. In such an embodiment, a mask pattern (not shown) may be formed on the first surface of the wafer 100 by means of a photolithography process to define the first and second preliminary holes 125 and 130. Using the mask pattern as a mask, the wafer 100 is etched to form the first and second preliminary holes 125 and 130. In another embodiment, the first and second preliminary holes 125 and 130 may be formed using a laser beam. For example, the laser beam may be used to selectively irradiate laser light onto the first surface 102 of the wafer 100 to form the first and second preliminary holes 125 and 130.

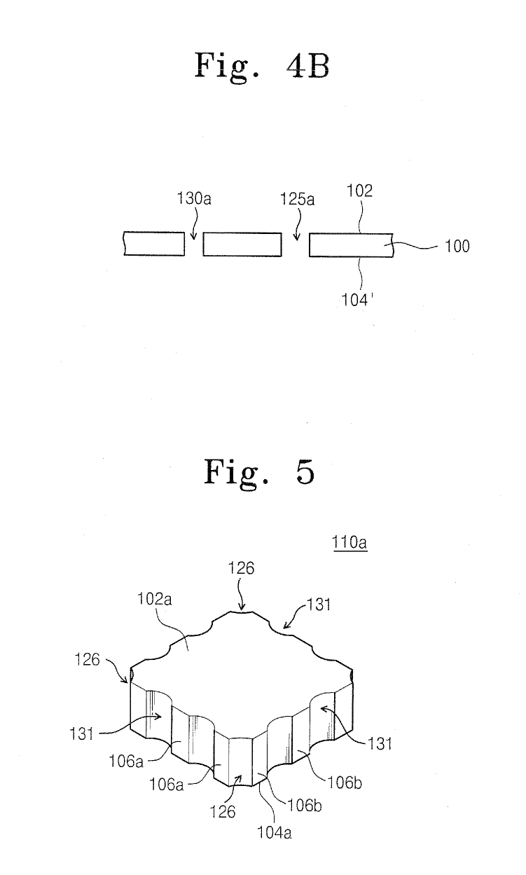

Referring to FIGS. 4A and 4B, the second surface 104 of the wafer 100, having the first and second preliminary holes 125 and 130 formed therein, may be thinned (e.g., ground). The thinning (e.g., grinding) may be conducted until, for example, the bottom surfaces of the first and second preliminary holes 125 and 130 are removed. Thus, the bottom surface of the first preliminary hole 125 may be removed during the thinning process to form a corresponding intersection hole 125a and the bottom surface of the second preliminary hole 130 may be removed during the thinning process to form a corresponding side hole 130a. The intersection hole 125a and the side hole 130a penetrate the thinned wafer 100′ having a second (e.g., ground) surface 104′. The intersection hole 125a penetrates the thinned wafer 100′ at an intersection of the first and second segment regions 115 and 117 and at the corner edge of the chip area 110 adjacent to the intersection. The side hole 130a penetrates the thinned wafer 100′ at a side portion, which is a portion of at least one of the first and second segment regions 115 and 117, and at the edge of the chip area 110 adjacent to the side portion.

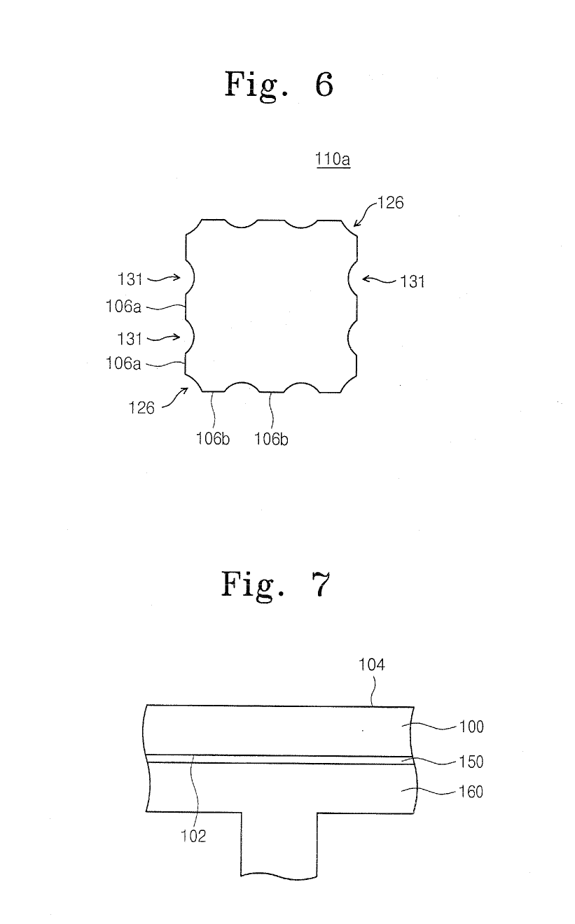

Along the scribe region 120 (i.e., along the first and second segment regions 115 and 117), the thinned wafer 100′ may be diced into separate adjacent chip areas 110. In one embodiment, the wafer 100′ may be diced using a dice blade. In another embodiment, the wafer 100′ may be diced using a laser beam. Each of the separate chip areas 110 may constitute a semiconductor chip 110a, as exemplarily illustrated in FIGS. 5 and 6.

FIGS. 5 and 6 are a perspective view and a top plan view of a semiconductor chip 110a according to an embodiment of the present invention, respectively.

Referring to FIGS. 5 and 6, the semiconductor chip 110a may, for example, include a first surface 102a where semiconductor devices are to be formed and a second surface 104a that is opposite to the first surface 102a. Further, the semiconductor chip 110a may include a rim side connecting an edge of the first surface 102a with an edge of the second surface 104a. The rim side includes a first side surface 106a extending in a first direction, a second side surface 106b extending in a second direction and a corner side surface connecting the first and second side surfaces 106a and 106b. The first and second directions may be different from each other. In one embodiment, the first and second directions may be substantially perpendicular to each other. The rim side may include four side surfaces (e.g., a pair of opposing first side surfaces 106a and a pair of opposing second side surfaces 106b).

Grooves 126 and 131 may be defined within the rim side toward the second surface 104a from the first surface 102a. That is, grooves 126 and 131 extend to the second surface 104a from the first surface 102a. For example, a corner groove 126 may be disposed so as to connect the first and second side surfaces 106a and 106b and a side groove 131 may be disposed at one or both of the first and second side surfaces 106a and 106b. As illustrated, the corner groove 126 is a portion of the sidewall of a previously formed intersection hole 125a, and the side groove 131 is a portion of the sidewall of a previously formed side hole 130a. Therefore, inner surfaces of the corner groove 126 and the side groove 131 are concave surfaces (e.g., concavely curved surfaces). As broadly used herein, the term “curved” or “curve” means not straight or containing no angles (i.e., a figure formed by two rays or planes that intersect). Accordingly, at least a portion of the grooves 126 and 131 may include a rounded portion (e.g., a circular portion, an oval-type portion, etc.) Accordingly, the corner side surface of the semiconductor chip 110a may be concavely curved. A plurality of side grooves 131 may be formed at the respective side surfaces 106a and 106b.

In one embodiment, the semiconductor chip 110a may have one or a plurality of corner grooves 126 only. In another embodiment, the semiconductor chip 110a may have one or a plurality of side grooves 131 only. In another embodiment, the semiconductor chip 110a may have one or a plurality of both corner and side grooves 126 and 131.

According to the method exemplarily described above, holes 125a and 130a may be formed within the thinned wafer 100′ having a small thickness. Warpage of the wafer 100′ may be suppressed due to the presence of holes 125a and 130a. Accordingly, the stress of a material layer formed on the wafer 100′ may be reduced as compared to the stress of a material layer formed on the wafer W of the prior art due to the holes 125a and 130a. Warpage of the semiconductor chip 110a may also be suppressed due to the presence of grooves 126 and 131 formed by the holes 125a and 130a.

Be Core dicing the thinned wafer 100′, the corner groove 126 may be formed at the corner of the chip area 110 by the intersection hole 125a. Thus, the wafer 100′ may be checked to determine the presence of cracks when the wafer 100′ is diced or when the semiconductor chip 110a is handled. If the corner side surface of the semiconductor chip 110a is angled (i.e., not curved), then a crack may be formed at the corner due to various frictions present during a dicing process and/or a chip handling process. Nevertheless, the crack of the semiconductor chip 110a is checked because the corner groove 126 is formed at the corner of the semiconductor chip 110a.

There may be a modified method of forming the holes 125a and 130a. The modified method does not require formation of preliminary holes, which will be exemplarily described in detail below.

FIGS. 7 through 9 are cross-sectional views illustrating a modified step of forming holes in the method described with reference to FIGS. 2A, 3A and 4A.

Referring to FIG. 7, an adhesive 150 (e.g., adhesive tape) may be bonded to a first surface 102 of a wafer 100 to protect semiconductor devices. The wafer 100 with the adhesive 150 bonded thereon is then loaded on a chuck 160. The adhesive 150 contacts a top surface of the chuck 160, thereby exposing a second surface 104 of the wafer 100. The wafer 100 may be fixed onto the chuck 160 using a wafer fixing means (e.g., by a vacuum pressure applied from the chuck 160).

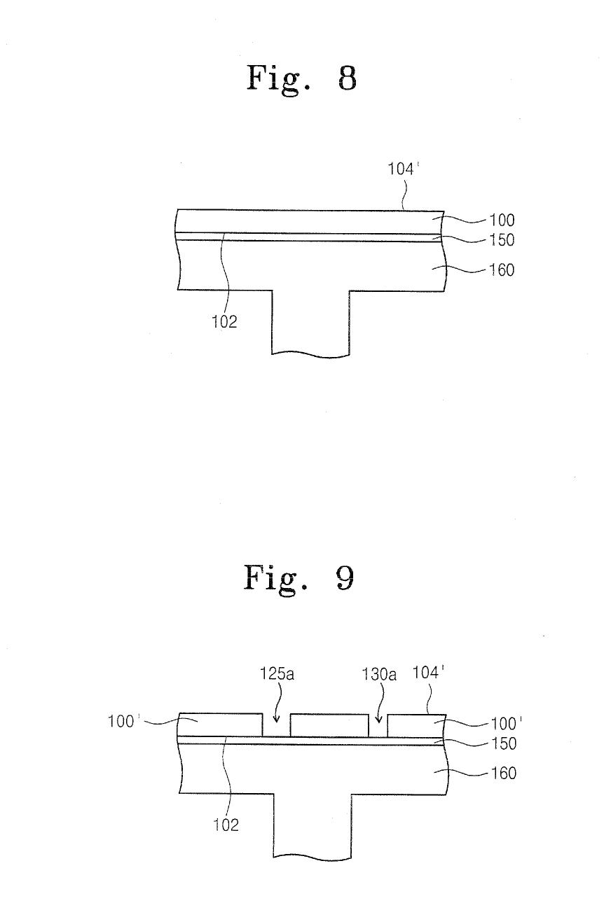

Referring to FIG. 8, the second surface 104 of the wafer 100 may be thinned. As a result, the thinned wafer 100′ having the second (e.g., ground) surface 104′ is formed to a target thickness.

Referring to FIG. 9, intersection and side holes 125a and 130a are formed to penetrate the thinned wafer 100′. In one embodiment, the intersection hole 125a and the side hole 130a may formed using a laser beam, Accordingly, means for irradiating a laser beam may be disposed over the chuck 160 and a laser beam may be selectively irradiated to the thinned wafer 100′ to form the intersection and side holes 125a and 130a. In one embodiment, the thinning process and the process of irradiating laser beam to form the holes 125a and 130a may be performed in-situ within a semiconductor apparatus including the chuck 160. The laser beam irradiated positions of the wafer 100′ may be controlled by moving the chuck 160 and/or the means for irradiating laser beam.

### Embodiment 2

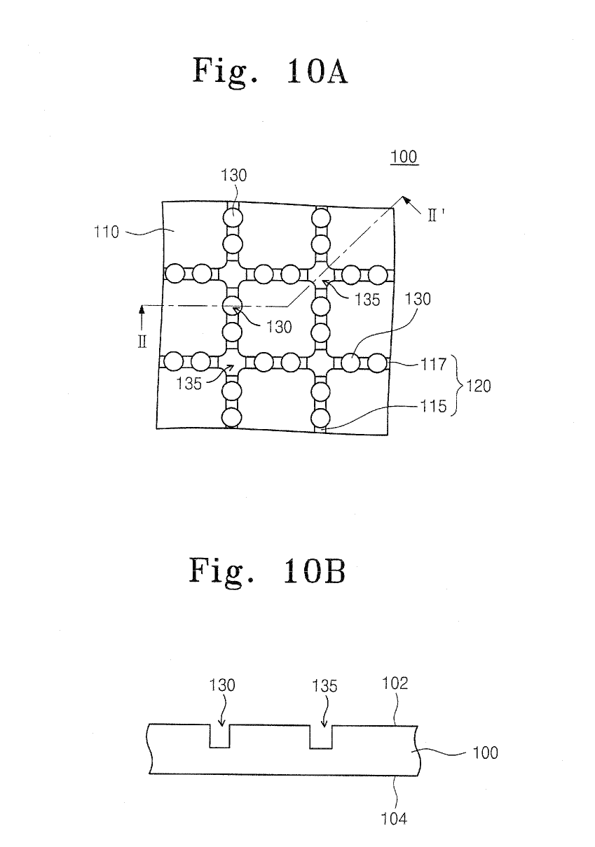

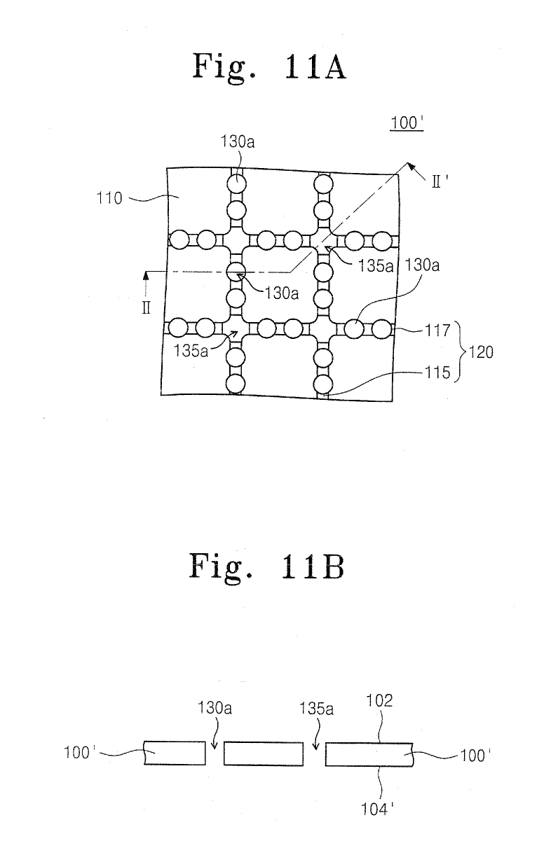

FIGS. 10A and 11A are top plan views illustrating a method of forming a semiconductor chip according to another embodiment of the present invention. FIGS. 10B and 11B are cross-sectional views taken along lines II-II′ of FIGS. 10A and 11A, respectively.

Referring to FIGS. 10A and 10B, a wafer 100 may be provided with a first surface 102 where a plurality of chip areas 110 and a scribe region 120 between the chip areas 110 are formed and a second surface 104 that is opposite to the first surface 102. The chip areas 110 and the scribe region 120 may be the same as those previously described with respect to the first embodiment.

A first preliminary hole 135 and a second preliminary hole 130 may be formed to a predetermined depth below the first surface 102 of the wafer 100. The depth may be substantially equal to or larger than the thickness of a subsequently formed semiconductor chip.

The first and second preliminary holes 135 and 130 are formed at portions of the scribe region 120 and at the edge portions of the chip area 110 adjacent thereto. For example, the first preliminary hole 135 may be formed at an intersection of the first and second segment regions included in the scribe region 120 and at the corner edge of the chip area 110 adjacent to the intersection. The first preliminary hole 135 may be formed to make the corner side surface of the chip area 110 curved. For example, the first preliminary hole 135 includes at least one curved side protruding inwardly toward a center of the first preliminary hole 135. Accordingly, the corner side surface of the chip area 110 may be provided as a convexly curved (e.g., convexly round) surface, when viewed from the inside of the first preliminary hole 135. On the contrary, the corner side surface of the chip area 110 may be provided as a concavely curved surface, when viewed from the outside of the first preliminary hole 135. In one embodiment, the sidewall of the first preliminary hole 135 may be slanted. The second preliminary hole 130 have the same shape as exemplarily described above with respect to the first embodiment.

The first and second preliminary holes 135 and 130 may be spaced apart from each other and two-dimensionally arranged along the scribe region 120 in row and column directions.

In one embodiment, the first and second preliminary holes 135 and 130 of the second embodiment may be formed according to a patterning process including, for example, a photolithography process and an etching process (e.g., as described above with respect to the first embodiment). In another embodiment, the first and second preliminary holes 135 and 130 may be formed by selectively irradiating laser beam onto the wafer 100.

Referring to FIGS. 11A and 11B, the second surface 104 of the wafer 100 may be thinned until bottom surfaces of the first and second preliminary holes 135 and 130 are removed. As a result, an intersection hole 135a and a side hole 130a may be formed to penetrate the thinned wafer 100′ having the second (e.g., ground) surface 104′. Accordingly, the bottom surface of the first preliminary hole 135 may be removed to form a corresponding intersection hole 135a and the bottom surface of the second preliminary hole 130 may be removed to form a corresponding side hole 130a.

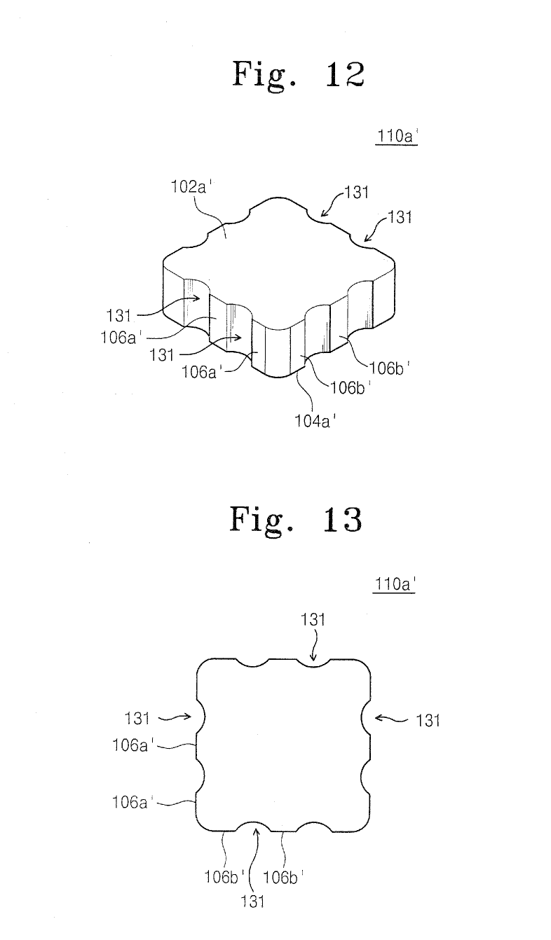

The thinned wafer 100′ may be diced along the scribe region 120 to separate the chip areas 110. The thinned wafer 100′ may be diced using, for example, a dicing blade or laser beam. Each of the separate chip areas 110 may constitute a semiconductor chip 110a′, as exemplarily illustrated in FIGS. 12 and 13.

FIGS. 12 and 13 are a perspective view and a top plan view of a semiconductor chip 110a′ according to another embodiment of the present invention, respectively.

Referring to FIGS. 12 and 13, the semiconductor chip 110a′ may include a first surface 102a′ where semiconductor devices are to be formed and a second surface 104a′ that is opposite to the first surface 102a′. The semiconductor chip 110a′ may further include a rim side, which includes a first side surface 106a′ extending in a first direction, a second side surface 106b′ extending in a second direction and a corner side surface connecting the first and second side surfaces 106a′ and 106b′. The first and second directions may be different from each other. In one embodiment, the first and second directions may be substantially perpendicular to each other. The rim side may include four side surfaces (e.g., a pair of opposing first side surfaces 106a′ and a pair of opposing second side surfaces 106b′).

At least one side groove 131 may be defined within the rim side toward the second surface 104a′ from the first surface 102a′. For example, a side groove 131 may be disposed at one or both of the first and second side surfaces 106a′ and 106b′. As illustrated, the side groove 131 is a portion of the sidewall of a previously formed side hole 130a. The corner side surface connecting the first and second side surfaces 106a′ and 106b′ is convexly curved (e.g., convexly round). As illustrated, the convexly curved corner side surface is a portion of the sidewall of previously formed intersection hole 135a.

According to the method exemplarily described above, the holes 135a and 130a may be formed within the thinned wafer 100′ having a small thickness to suppress the wafer warpage. Warpage of the semiconductor chip 110a′ may also be suppressed due to the presence of the side groove 131 and/or the convexly curved corner. Further, the side groove 131 and/or the convexly curved corner side surface facilitate the inspection of cracks which may be generated during a dicing process and/or a handling process of the semiconductor chip 110a′.

The intersection hole and side holes 135a and 130a may be formed by the modified method described with reference to FIGS. 7 through 9. Accordingly, after thinning the wafer 100 (e.g., after grinding the second surface 104 of the wafer 100), a laser beam may be selectively irradiated onto the second (e.g., ground) surface 104′ to form the intersection hole and side holes 135a and 130a shown in FIGS. 11A and 11B. The thinning process and the process of irradiating laser beam to form the holes 135a and 130a may be performed in-situ.

As exemplarily describe above, holes may be formed to penetrate a wafer having chip areas and a scribe region. Accordingly, the stress applied to a relatively thin wafer may be reduced to suppress the warpage of the wafer. The holes may be formed at portions of the scribe region and the edge of the chip areas adjacent to the portions of the scribe region. Thus, a portion of the hole may be formed within a semiconductor chip to suppress warpage of the semiconductor chip. Due to the presence of the hole, the corner side surface may be concavely curved or may be convexly curved to prevent the generation of cracks during a dicing process and/or a semiconductor chip handling process.

Although the embodiments of the present invention have been described in connection with the accompanying drawings, they are not limited thereto. It will be apparent to those skilled in the art that various substitutions, modifications and changes may be made without departing from the scope and spirit of the invention.

What is claimed is:

1. A semiconductor chip comprising:
a first surface;
a second surface opposite to the first surface;
a rim side connecting the first surface and the second surface; and
at least one groove defined within rim side, wherein the groove extends from the first surface to the second surface and wherein at least a portion of the groove is curved.

2. The semiconductor chip as recited in claim 1, wherein the rim side comprises a first side surface extending in a first direction and a second side surface extending in a second direction,
wherein the groove comprises a corner groove connecting the first and second side surfaces.

3. The semiconductor chip as recited in claim 2, wherein the corner groove is concavely curved toward an interior of the semiconductor chip.

4. The semiconductor chip as recited in claim 2, wherein the groove further comprises a side groove defined within at least one of the first and second side surfaces.

5. The semiconductor chip as recited in claim 4, wherein the side groove is concavely curved toward an interior of the semiconductor chip.

6. The semiconductor chip as recited in clam 1, wherein the rim side comprises a first side surface extending in a first direction and a second side surface extending in a second direction,
wherein the groove comprises a side groove defined within at least one of the first and second side surfaces.

7. The semiconductor chip as recited in clam 6, wherein a corner side surface connecting the first and second side surfaces is convexly curved away from an interior of the semiconductor chip.

8. The semiconductor chip as recited in claim 6, wherein the side groove is concavely curved toward an interior of the semiconductor chip.

9. A method of forming a semiconductor chip, the method comprising:
preparing a wafer comprising a first surface and a second surface opposite to the first surface, wherein a plurality of chip areas are arranged on the first surface and a scribe region is located between the plurality of chip areas;
forming a hole within a portion of the scribe region and a chip area, the hole penetrating the wafer, wherein at least a portion of the hole is curved; and
dicing the wafer along the scribe region to separate adjacent ones of the plurality of chip areas, wherein a separated chip areas is a semiconductor chip and wherein a portion of a rim side connecting the first and second surfaces corresponds to a portion of a sidewall of the hole.

10. The method as recited in claim 9, wherein forming the hole comprises:
forming a preliminary hole to a predetermined depth below the first surface of the wafer; and
thinning the wafer to remove the bottom surface of the preliminary hole, wherein the thinned wafer comprises the first surface.

11. The method as recited in claim 10, wherein forming the preliminary hole includes irradiating a laser beam onto the first surface of the wafer or performing photolithography and etching processes.

12. The method as recited in claim 9, wherein forming the hole comprises:
thinning the wafer; and
irradiating a laser beam onto the thinned wafer.

13. The method as recited in claim 9, wherein the scribe region comprises a first segment region extending in a first direction and a second segment region extending in a second direction,
wherein the rim side of the semiconductor chip comprises a first side surface extending in the first direction and a second side surface extending in the second direction.

14. The method as recited in claim 13, wherein forming the hole comprises:
forming an intersection hole penetrating the wafer at an intersection of the first and second segment regions, wherein the intersection hole penetrates the wafer at a corner edge portion of a chip area adjacent to the intersection.

15. The method as recited in claim 14, wherein the intersection hole is substantially cylindrical and wherein the rim side of the semiconductor chip comprises a corner groove connecting the first and second side surfaces.

16. The method as recited in claim 14, wherein forming the hole further comprises:
forming a side hole penetrating the wafer at a side portion of at least one of the first and second segment regions, wherein the side hole penetrates the wafer at a side edge portion of a chip area adjacent to the side portion.

17. The method as recited in claim 13, wherein forming the hole comprises:
forming a side hole penetrating the wafer at a side portion of at least one of the first and second segment regions, wherein the side hole penetrates the wafer at a side edge portion of a chip area adjacent to the side portion.

18. The method as recited in claim 17, wherein the side hole is substantially cylindrical and wherein the rim side of the semiconductor chip comprises a side groove defined within at least one of the first and second side surfaces.

19. The method as recited in claim 17, wherein forming the hole comprises:
forming an intersection hole penetrating the wafer at an intersection of the first and second segment regions, wherein the intersection hole penetrates the wafer at a corner edge portion of a chip area adjacent to the intersection, wherein the rim side comprises a corner side surface connecting the first and second side surfaces and wherein the corner side surface is convexly curved away from an interior of the semiconductor chip.

20. The method as recited in claim 13, wherein the forming a hole comprises:
forming an intersection hole penetrating the wafer at an intersection of the first and second segment regions, wherein the intersection hole penetrates the wafer at a corner edge portion of a chip area adjacent to the intersection, wherein the rim side of the semiconductor chip comprises a corner side surface connecting the first and second side surfaces and wherein the corner side surface is convexly curved away from an interior of the semiconductor chip.

21. A semiconductor chip, comprising:
a first surface;
a second surface opposite to the first surface;
a side surface connecting the first surface and the second surface; and
at least one groove defined within side surface and extending from the first surface to the second surface, wherein the groove divides the side surface into two portions which are substantially coplanar.

22. A semiconductor chip, comprising:
a first surface;
a second surface opposite to the first surface;
a rim side connecting the first surface and the second surface, the rim side comprising a first side surface extending in a first direction, a second side surface extending in a second direction and a corner connecting the first and second side surfaces; and
at least one groove defined within at least one of the first and second side surfaces, wherein the at least one groove extends from the first surface to the second surface and wherein the groove is spaced apart from the corner.
